(19) United States
(12) Patent Application Publication
(10) Pub. No.: US 2019/0305145 A1
(43) Pub. Date: Oct. 3, 2019

(54) SOLAR CELL MODULE AND SOLAR CELL INCLUDING COLLECTING ELECTRODES ON BOTH SURFACES

(71) Applicant: Panasonic Intellectual Property Management Co., Ltd., Osaka (JP)

(72) Inventors: Shigeharu TAIRA, Osaka (JP); Shinji KOBAYASHI, Shimane (JP); Yuzuru MIYATA, Shimane (JP)

(21) Appl. No.: 16/447,730

(22) Filed: Jun. 20, 2019

Related U.S. Application Data
(63) Continuation of application No. PCT/JP2017/033600, filed on Sep. 15, 2017.

(30) Foreign Application Priority Data
Dec. 22, 2016 (JP) 2016-249886

(51) Int. Cl. H01L 31/02; H01L 31/05; H01L 31/0224

(52) U.S. Cl. CPC H01L 31/02008; H01L 31/022425; H01L 31/0504

(57) ABSTRACT

A total of n light receiving surface finger electrodes are arranged on a light receiving surface. A total of (n−1)×m1/m2+1 second collecting electrodes are arranged on a back surface. On a plane of projection parallel, m2 light receiving surface finger electrodes and ml back surface finger electrodes are included an interval between a first position and a second position. On the plane of projection, the auxiliary wiring is provided at a third position at which only the light receiving surface finger electrode is present. A length of the auxiliary wiring is smaller than a length of the back surface finger electrode.

### CROSS-REFERENCE TO RELATED APPLICATION

This application is a Continuation of International Application No. PCT/JP2017/033600, filed on Sep. 15, 2017, which is based upon and claims the benefit of priority from the prior Japanese Patent Application No. 2016-249886, filed on Dec. 22, 2016, the entire contents of which are incorporated herein by reference.

### BACKGROUND

### 1. Field

The present disclosure relates to a solar cell module and a solar cell including collecting electrodes on both surfaces.

### 2. Description of the Related Art

In a solar cell module, a plurality of solar cells are connected by inter-cell wiring members. In the step of connection, the inter-cell wiring members are pressurized toward the finger electrode formed on the surface of the solar cell. If the finger electrode formed on the light receiving surface of the solar cell and the finger electrode formed on the back surface are completely misaligned, a shearing stress is exerted to the solar cell when the inter-cell wiring member is pressurized. If a load from the shearing stress is collected in the solar cell, a crack occurs easily. In an approach to prevent this, the finger electrode formed on the light receiving surface and the finger electrode formed on the back surface are arranged to overlap each other on a plane of projection parallel to the light receiving surface (JP2008-235354).

For the purpose of improving the efficiency of collecting power generated in a solar cell, it is desired to configure the number of finger electrodes formed on the back surface to be larger than the number of finger electrodes formed on the light receiving surface. Further, the number of finger electrodes formed on the back surface is configured to be an integral multiple of the number of finger electrodes formed on the light receiving surface to inhibit cracks from occurring. However, since the finger electrode is formed by using a material that contains a noble metal such as silver paste, an increase in the number of finger electrodes formed on the back surface results in an increase in the cost of the solar cell. It is therefore not desired to increase the number of finger electrodes more than necessary.

### SUMMARY

The disclosure addresses the above-described issue, and a general purpose thereof is to provide a technology of inhibiting cracks from occurring without configuring the number of finger electrodes formed on the back surface to be an integral multiple of the number of finger electrodes provided on the side of the light receiving surface.

A solar cell module according to an embodiment of the present disclosure includes: a plurality of solar cells including a first surface and a second surface that face in opposite directions; and a wiring member that connects, of the plurality of solar cells, two solar cells adjacent in a first direction. Each of the plurality of solar cells includes: n first collecting electrodes arranged on the first surface in the first direction; (n−1)×m1/m2+1 second collecting electrodes arranged on the second surface in the first direction; and one or more auxiliary wirings arranged on the second surface in the first direction. On a plane of projection parallel to the first surface or the second surface, m2 first collecting electrodes and m1 second collecting electrodes are included an interval between a first position at which the first collecting electrode and the second collecting electrode overlap and a second position at which the first collecting electrode and the second collecting electrode overlap next, the interval starting from the first position in the first direction, on the plane of projection parallel to the first surface or the second surface, the auxiliary wiring is provided on the second surface at a third position at which only the first collecting electrode is present, a length of the auxiliary wiring in a second direction intersecting the first direction is smaller than a length of the second collecting electrode in the second direction, and the wiring member is connected to the second collecting electrode and the auxiliary wiring on the second surface of the solar cell.

Another embodiment of the present disclosure relates to a solar cell. A solar cell includes a first surface and a second surface that face in opposite directions; and n first collecting electrodes arranged on the first surface in the first direction; (n−1)×m1/m2+1 second collecting electrodes arranged on the second surface in the first direction; and one or more auxiliary wirings arranged on the second surface in the first direction. On a plane of projection parallel to the first surface or the second surface, m2 first collecting electrodes and m1 second collecting electrodes are included an interval between a first position at which the first collecting electrode and the second collecting electrode overlap and a second position at which the first collecting electrode and the second collecting electrode overlap next, the interval starting from the first position in the first direction, on the plane of projection parallel to the first surface or the second surface, the auxiliary wiring is provided on the second surface at a third position at which only the first collecting electrode is present, and a length of the auxiliary wiring in a second direction intersecting the first direction is smaller than a length of the second collecting electrode in the second direction.

### BRIEF DESCRIPTION OF THE DRAWINGS

The figures depict one or more implementations in accordance with the present teaching, by way of example only, not by way of limitations. In the figures, like reference numerals refer to the same or similar elements.

FIG. 1 is a plan view of a solar cell module according to an embodiment of the present disclosure as viewed from a light receiving surface side;

FIG. 2 is a cross-sectional view of the solar cell module of FIG. 1;

FIGS. 3A-3B are plan views showing the structure of the solar cell of FIG. 1;

FIG. 4 is a cross-sectional view of the solar cell; and

FIGS. 5A-5B are plan views showing another structure of the solar cell of FIG. 1.

### DETAILED DESCRIPTION

The invention will now be described by reference to the preferred embodiments. This does not intend to limit the scope of the present invention, but to exemplify the invention.

A brief summary will be given before describing the disclosure in specific details. An embodiment of the present disclosure relates to a solar cell module including a plurality of solar cells. Each solar cell has a light receiving surface and a back surface. A plurality of finger electrodes (hereinafter, referred to as “light receiving surface finger electrodes”) are provided on the light receiving surface side, and a plurality of finger electrodes (hereinafter, referred to as “back surface finger electrodes”) are provided on the back surface side. The plurality of light receiving surface finger electrodes and the plurality of back surface finger electrodes in two adjacent solar cells are connected by wiring members. Since the amount of solar light incident on the light receiving surface is larger than that of the back surface in a solar cell of this type, the light receiving surface contributes to power generation more than the back surface. For this reason, the number of back surface finger electrodes is configured to be larger than the light receiving surface finger electrodes in order to improve the efficiency of collecting power generated in the solar cell.

Also, back surface finger electrodes are arranged to overlap light receiving surface finger electrodes on a plane of projection parallel to the light receiving surface or the back surface (hereinafter, sometimes simply referred to as “plane of projection”) in order to inhibit cracks from occurring in the solar cell and to improve the yield. In view of this background, the number of back surface finger electrodes is configured to be an integral multiple of the number of light receiving surface finger electrodes. Meanwhile, in case the light receiving surface finger electrodes and the back surface finger electrodes are formed by a noble metal, an increase in the number results in an increase in the cost of the solar cell. It is therefore desired to inhibit the number of finger electrodes from increasing and, at the same time, to inhibit cracks from occurring on the condition that the number of back surface finger electrodes is configured to be larger than the number of light receiving surface finger electrodes.

To address the issue, the number of back surface finger electrodes is not configured to be an integral multiple of the number of light receiving surface finger electrodes in this embodiment. This results in the back surface finger electrode overlapping the light receiving surface finger electrode periodically on a plane of projection. There are also light receiving surfaces finger electrodes that the back surface finger electrode does not overlap. Auxiliary wirings are provided on the back surface to overlap such light receiving surface finger electrodes. An auxiliary wiring has a structure similar to that of the back surface finger electrode but is configured to be shorter than the back surface finger electrode. Accordingly, the light receiving surface finger electrode and the auxiliary wiring overlap to inhibit cracks from occurring. The use of the auxiliary wiring reduces the use of a noble metal. The terms “parallel” and “orthogonal” in the following description not only encompass completely parallel or orthogonal but also encompass slightly off-parallel within the margin of error. The term “substantially” means identical within certain limits.

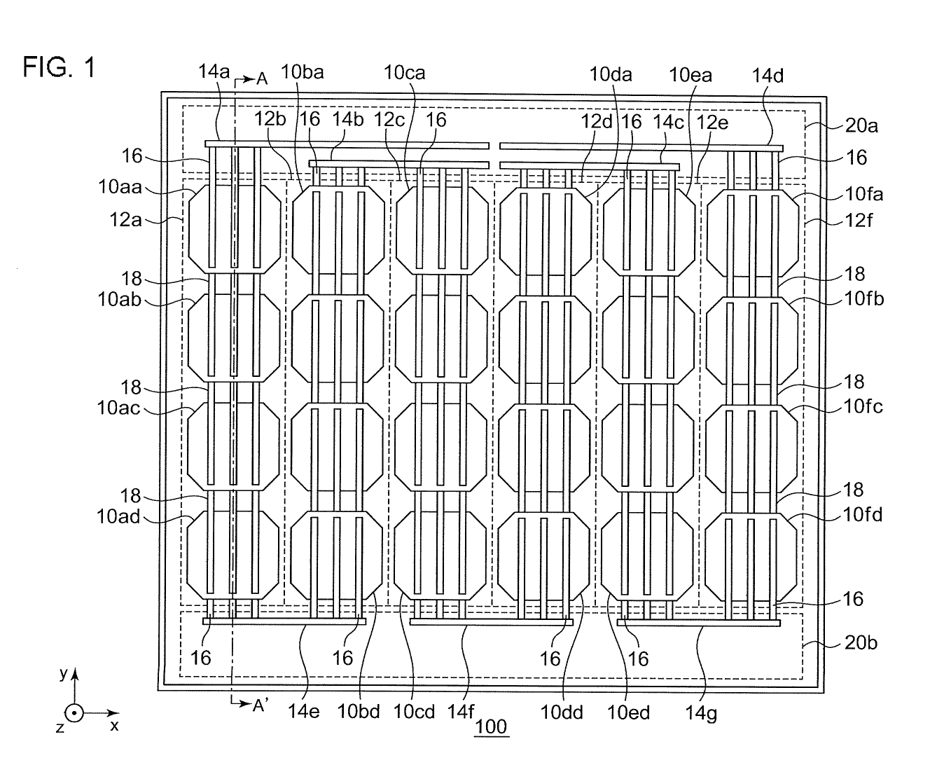

FIG. 1 is a plan view of a solar cell module 100 according to an embodiment of the present disclosure as viewed from a light receiving surface side. As shown in FIG. 1, an orthogonal coordinate system including an x axis, y axis, and a z axis is defined. The x axis and y axis are orthogonal to each other in the plane of the solar cell module 100. The z axis is perpendicular to the x axis and y axis and extends in the direction of thickness of the solar cell module 100. The positive directions of the x axis, y axis, and z axis are defined in the directions of arrows in FIG. 1, and the negative directions are defined in the directions opposite to those of the arrows. Of the two principal surfaces forming the solar cell module 100 that are parallel to the x-y plane, the principal surface disposed on the positive direction side along the z axis is the light receiving surface, and the principal surface disposed on the negative direction side along the z axis is the back surface. Hereinafter, the positive direction side along the z axis will be referred to as “light receiving surface side” and the negative direction side along the z axis will be referred to as “back surface side”. When the y axis direction is referred to as the “first direction”, the x axis direction is referred to as the “second direction”.

The solar cell module 100 includes an 11th solar cell 10aa, . . . , a 64th solar cell 10fd, which are generically referred to as solar cells 10, a first bridge wiring member 14a, a second bridge wiring member 14b, a third bridge wiring member 14c, a fourth bridge wiring member 14d, a fifth bridge wiring member 14e, a sixth bridge wiring member 14f, a seventh bridge wiring member 14g, which are generically referred to as bridge wiring members 14, a cell end wiring member 16, and an inter-cell wiring member 18. A first non-generating area 20a and a second non-generating area 20b are disposed to sandwich the plurality of solar cells 10 in the y axis direction. More specifically, the first non-generating area 20a is disposed farther on the positive direction side along the y axis than the plurality of solar cells 10, and the second non-generating area 20b is disposed further on the negative direction side along the y axis than the plurality of solar cells 10. The first non-generating area 20a and the second non-generating area 20b (hereinafter, sometimes generically referred to as “non-generating areas 20”) have a rectangular shape and do not include the solar cells 10.

Each of the plurality of solar cells 10 absorbs incident light and generates photovoltaic power. The solar cell 10 is made of, for example, a semiconductor material such as crystalline silicon, gallium arsenide (GaAs), or indium phosphorus (InP). Details of the features of the solar cell 10 will be described later. It is assumed here that the solar cell 10 is a hetero-junction solar cell. A plurality of finger electrodes extending in the x axis direction in a mutually parallel manner and a plurality of (e.g., three) bus bar electrodes extending in the y axis direction to be orthogonal to the plurality of finger electrodes are disposed on the light receiving surface and the back surface of each solar cell 10 although the finger electrodes and the bus bar electrodes are omitted in FIG. 1. The bus bar electrodes connect the plurality of finger electrodes to each other. The bus bar electrodes and the finger electrodes are formed by, for example, silver paste or the like.

The plurality of solar cells 10 are arranged in a matrix on the x-y plane. By way of example, six solar cells 10 are arranged in the x axis direction and four solar cells are arranged in the y axis direction. The number of solar cells 10 arranged in the x axis direction and the number of solar cells 10 arranged in the y axis direction are not limited to the examples above. The four solar cells 10 arranged and disposed in the y axis direction are connected in series by the inter-cell wiring member 18 so as to form one solar cell string 12. For example, by connecting the 11th solar cell 10aa, a 12th solar cell 10ab, a 13th solar cell 10ac, and a 14th solar cell 10ad, a first solar cell string 12a is formed. The other solar cell strings 12 (e.g., a second solar cell string 12b through a sixth solar cell string 12f) are similarly formed. As a result, the six solar cell strings 12 are arranged in parallel in the x axis direction.

In order to form the solar cell strings 12, the inter-cell wiring members 18 connect the bus bar electrode on the light receiving surface side of one of adjacent solar cells 10 to the bus bar electrode on the back surface side of the other solar cell 10. For example, the three inter-cell wiring members 18 for connecting the 11th solar cell 10aa and the 12th solar cell 10ab electrically connect the bus bar electrode on the back surface side of the 11th solar cell 10aa and the bus bar electrode on the light receiving surface side of the 12th solar cell 10ab.

Four of the seventh bridge wiring members 14 are provided in the first non-generating area 20a, and the remaining three are provided in the second non-generating area 20b. Each of the fifth bridge wiring member 14e through the seventh bridge wiring member 14g provided in the second non-generating area 20b extends in the x axis direction and is electrically connected to two adjacent solar cell strings 12 via the cell end wiring member 16. For example, the fifth bridge wiring member 14e is electrically connected to the 14th solar cell 10ad in the first solar cell string 12a and the 24th solar cell 10bd in the second solar cell string 12b. The cell end wiring member 16 is provided on the light receiving surface or the back surface of the solar cell 10 in a manner similar to that of the inter-cell wiring member 18.

The first bridge wiring member 14a provided in the first non-generating area 20a is connected to the 11th solar cell 10aa of the first solar cell string 12a via the cell end wiring member 16. The first bridge wiring member 14a extends from a portion of connection with the cell end wiring member 16 as far as the neighborhood of the center of the solar cell module 100 in the y axis direction. The second bridge wiring member 14b is connected to the 21th solar cell 10ba of the second solar cell string 12b via the cell end wiring member 16. The second bridge wiring member 14b is also connected to the 31st solar cell 10ca of the third solar cell string 12c via another cell end wiring member 16. Through these connections, the second bridge wiring member 14b electrically connects the second solar cell string 12b and the third solar cell string 12c.

The third bridge wiring member 14c and the fourth bridge wiring member 14d are in a mirror arrangement with respect to the second bridge wiring member 14b and the first bridge wiring member 14a in the x axis direction. Therefore, the first solar cell string 12a through the sixth solar cell string 12f are electrically connected. A lead wiring member (not shown) is connected to each of the first bridge wiring member 14a through the fourth bridge wiring member 14d, and the lead wiring members are connected to a terminal box (not shown).

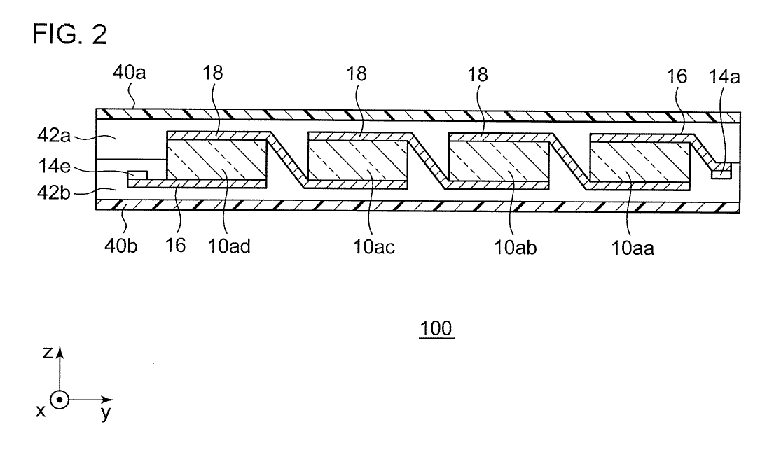

FIG. 2 is a cross-sectional view of the solar cell module 100 and is an A-A cross-sectional view of FIG. 1. The solar cell module 100 includes the 11th solar cell 10aa, the 12th solar cell 10ab, the 13th solar cell 10ac, the 14th solar cell 10ad, which are generically referred to as solar cells 10, the first bridge wiring member 14a, the fifth bridge wiring member 14e, the cell end wiring member 16, the inter-cell wiring member 18, a first protective member 40a, a second protective member 40b, which are generically referred to as protective members 40, a first encapsulant 42a, a second encapsulant 42b, which are generically referred to as encapsulants 42. The top of FIG. 2 corresponds to the light receiving surface side, and the bottom corresponds to the back surface side.

The first protective member 40a is disposed on the light receiving surface side of the solar cell module 100 and protects the surface of the solar cell module 100. The first protective member 40a is formed by using a translucent and water shielding glass, translucent plastic, etc. and is formed in a rectangular shape. In this case, it is assumed that glass is used. The first encapsulant 42a is stacked on the back surface side of the first protective member 40a. The first encapsulant 42a is disposed between the first protective member 40a and the solar cell 10 and adhesively bonds the first protective member 40a and the solar cell 10. For example, a thermoplastic resin film of polyolefin, ethylene-vinyl acetate copolymer (EVA), polyvinyl butyral (PVB), polyimide, or the like may be used as the first encapsulant 42a. A thermosetting resin may alternatively be used. The first encapsulant 42a is formed by a translucent, rectangular sheet member having a surface of substantially the same dimension as the x-y plane in the first protective member 40a.

The second encapsulant 42b is stacked on the back surface side of the first encapsulant 42a. The second encapsulant 42b encapsulates the plurality of solar cells 10, the inter-cell wiring members 18, etc. between the second encapsulant 42b and the first encapsulant 42a. The second encapsulant 42b may be made of a material similar to that of the first encapsulant 42a. Alternatively, the second encapsulant 42b may be integrated with the first encapsulant 42a by heating the encapsulants in a laminate cure process.

The second protective member 40b is stacked on the back surface side of the second encapsulant 42b. The second protective member 40b protects the back surface side of the solar cell module 100 as a back sheet. For example, a resin film of polyethylene terephthalate (PET), etc. is used as the second protective member 40b. A stack film having a structure in which an Al foil is sandwiched by resin films, or the like may be used as the second protective member 40b. An Al frame may be attached around the solar cell module 100.

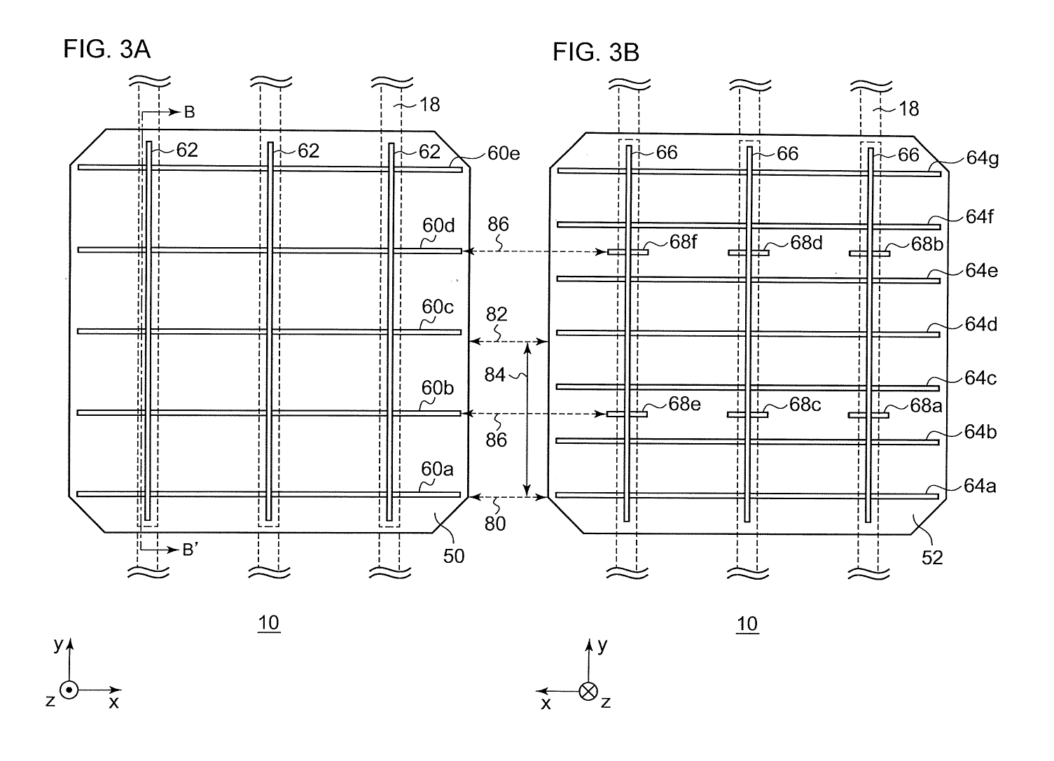

FIGS. 3A-3B are plan views showing the structure of the solar cell 10. In particular, FIG. 3A is a plan view of the solar cell 10 viewed from the side of the light receiving surface 50, and FIG. 3B is a plan view of the solar cell 10 viewed from the side of the back surface 52. When the light receiving surface 50 of the solar cell 10 is referred to as the first surface, the back surface 52 of the solar cell 10 is referred to as the second surface. The light receiving surface 50 and the back surface 52 of the solar cell 10 are formed in the shape of an octagon in which the longer side and the shorter side are alternately joined. The surfaces may be formed in other shapes. For example, the shorter side included in the octagon may be non-linear, or the surfaces may be shaped like a quadrangle.

A plurality of light receiving surface finger electrodes 60 extending in the x axis direction in a mutually parallel manner are disposed on the light receiving surface 50 of FIG. 3A. In this example, “five” light receiving surface finger electrodes 60 including the first light receiving surface finger electrode 60a through the fifth light receiving surface finger electrode 60e are arranged in the y axis direction as the plurality of light receiving surface finger electrodes 60. The number of the light receiving surface finger electrodes 60 is generically denoted by “n”. Further, a plurality of (e.g., 3) light receiving surface bus bar electrodes 62 extending in the y axis direction are disposed to intersect (e.g., be orthogonal to) the plurality of light receiving surface finger electrodes 60 on the light receiving surface 50. The light receiving surface bus bar electrode 62 connects the plurality of light receiving surface finger electrodes 60 to each other. The inter-cell wiring member 18 is disposed and layered upon each of the plurality of light receiving surface bus bar electrodes 62. Therefore, the three inter-cell wiring members 18 are arranged in the x axis direction and extend in the direction of the adjacent further solar cell 10, i.e., in the y axis direction.

A plurality of back surface finger electrodes 64 extending in the x axis direction in a mutually parallel manner are disposed on the back surface 52 of FIG. 3B. In this example, “seven” back surface finger electrodes 64 including a first back surface finger electrode 64a through a seventh back surface finger electrode 64g are arranged in the y axis direction as the plurality of back surface finger electrodes 64. Generalization of the number of the back surface finger electrodes 64 will be discussed later. The number of the back surface finger electrodes 64 is configured to be larger than the number of the light receiving surface finger electrodes 60. Further, three back surface bus bar electrodes 66 are provided on the back surface 52 as in the case of the light receiving surface 50. The inter-cell wiring member 18 is disposed and layered upon each of the plurality of back surface bus bar electrodes 66.

The first light receiving surface finger electrode 60a and the first back surface finger electrode 64a overlap on a plane of projection parallel to the light receiving surface 50 or the back surface 52. The plane of projection corresponds to the x-y plane. Also, the third light receiving surface finger electrode 60c and the fourth back surface finger electrode 64d overlap, and the fifth light receiving surface finger electrode 60e and the seventh back surface finger electrode 64g overlap on the plane of projection. In other words, some of the plurality of light receiving surface finger electrodes 60 and some of the plurality of back surface finger electrodes 64 overlap on the plane of projection.

The position at which the first light receiving surface finger electrode 60a and the first back surface finger electrode 64a overlap is indicated as a first position 80. Further, the next overlapping between the light receiving surface finger electrode 60 and the back surface finger electrode 64 in the positive direction along the y axis away from the first position 80 occurs between the third light receiving surface finger electrode 60c and the fourth back surface finger electrode 64d. Therefore, positions before a second position 82 at which the light receiving surface finger electrode 60 and the back surface finger electrode 64 overlap next in the positive direction along the y axis away from the first position 80 are located on side of the negative direction along the y axis relative to the position of the third light receiving surface finger electrode 60c and the fourth back surface finger electrode 64d.

The interval between the first position 80 and the second position 82 is indicated as a unit interval 84. The unit interval 84 can be said to be a segment in which non-overlapping continues since the light receiving surface finger electrode 60 and the back surface finger electrode 64 overlap. The unit interval 84 includes two light receiving surface finger electrodes 60 and three back surface finger electrodes 64. Denoting the number of the light receiving surface finger electrodes 60 included in the unit interval 84 as “m2” and the number of the back surface finger electrodes 64 as “m1”, the number of the back surface finger electrodes 64 on the back surface 52 is generalized as “(n−1)×m1/m2+1”, where m1>m2. The position at which the third light receiving surface finger electrode 60c and the fourth back surface finger electrode 64d overlap on the plane of projection may also be referred to as the first position 80. The second position 82 and the unit interval 84 are similarly defined for the first position 80 defined in this way.

The position on the plane of projection at which only the light receiving surface finger electrode 60 is present (e.g., the position at which the second light receiving surface finger electrode 60b is present without overlapping the light receiving surface bus bar electrode 62) is indicated as a third position 86. The third position 86 is also defined for the fourth light receiving surface finger electrode 60d. At the third position 86, an auxiliary wiring 68 is provided on the back surface 52. To describe it more specifically, a first auxiliary wiring 68a, a third auxiliary wiring 68c, and a fifth auxiliary wiring 68e are provided on the back surface 52 at the third position 86 defined for the second light receiving surface finger electrode 60b. Also, a second auxiliary wiring 68b, a fourth auxiliary wiring 68d, and a sixth auxiliary wiring 68f are provided on the back surface 52 at the third position 86 defined for the fourth light receiving surface finger electrode 60d. Since the plurality of auxiliary wirings 68 are arranged in the y axis direction along the inter-cell wiring member 18, the auxiliary wirings 68 are connected to the inter-cell wiring member 18.

On the back surface 52, three auxiliary wirings 68 are provided between the second back surface finger electrode 64b and the third back surface finger electrode 64c, and three auxiliary wirings 68 are provided between the fifth back surface finger electrode 64e and the sixth back surface finger electrode 64f. To generalize the feature, the auxiliary wirings 68 are provided on the back surface 52 so as to be positioned between the (m1−1)/2-th back surface finger electrode 64 and the (m1+1)/2-th back surface finger electrode 64, counting from the back surface finger electrode 64 at the first position 80 on the plane of projection, n being an odd number. The back surface finger electrode 64 at the first position 80 on the plane of projection corresponds to the first back surface finger electrode 64a and the fourth back surface finger electrode 64d in FIG. 3B.

Like the back surface finger electrode 64, the auxiliary wiring 68 is formed by silver paste or the like. The length of the auxiliary wiring 68 is smaller than the length of the back surface finger electrode 64 in the x axis direction. In particular, the length of the auxiliary wiring 68 is smaller than the interval between two adjacent inter-cell wiring members 18 and is larger than the width of the inter-cell wiring member 18. By providing the auxiliary wiring 68 as described above in place of the back surface finger electrode 64, the volume of noble metal such as silver paste used is reduced.

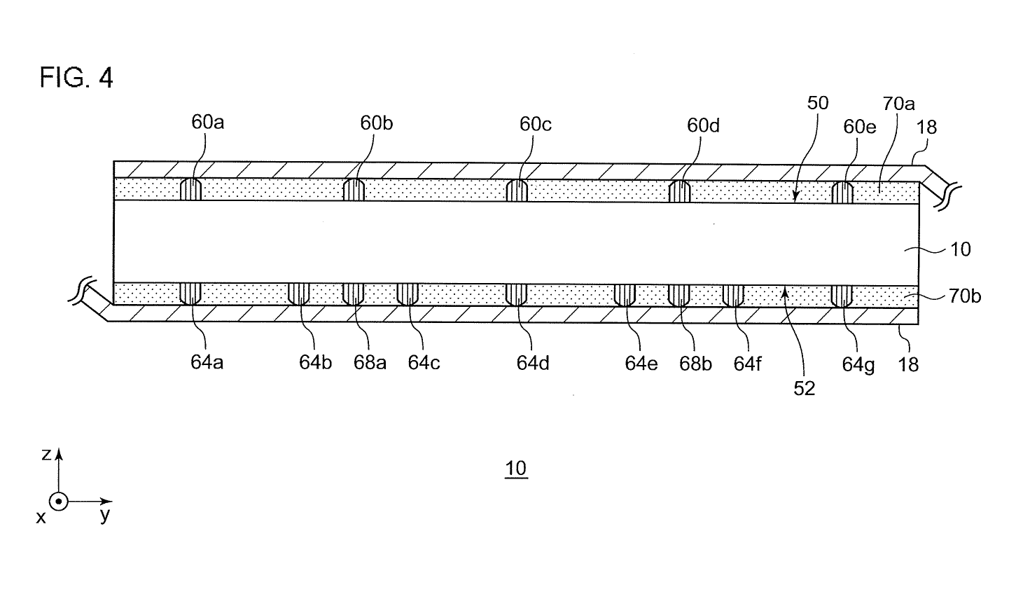

FIG. 4 is a cross-sectional view of the solar cell 10 and is an B-B′ cross-sectional view of FIG. 3A. In addition to the features shown in FIGS. 3A-3B, a first adhesion layer 70a and a second adhesion layer 70b, which are generically referred to as adhesion layers 70, are included. The top of FIG. 4 corresponds to the light receiving surface 50 and the bottom of FIG. 4 corresponds to the back surface 52.

The first light receiving surface finger electrode 60a through the fifth light receiving surface finger electrode 60e are provided on the light receiving surface 50 of the solar cell 10. The inter-cell wiring member 18 is adhesively bonded to the light receiving surface 50 via the first adhesion layer 70a. Therefore, the first light receiving surface finger electrode 60a through the fifth light receiving surface finger electrode 60e are electrically connected to the inter-cell wiring member 18. Meanwhile, the first back surface finger electrode 64a through the seventh back surface finger electrode 64g, the first auxiliary wiring 68a, and the second auxiliary wiring 68b are provided on the back surface 52 of the solar cell 10. Further, the inter-cell wiring member 18 is adhesively bonded to the back surface 52 via the second adhesion layer 70b. For this reason, the first back surface finger electrode 64a through the seventh back surface finger electrode 64g, the first auxiliary wiring 68a, and the second auxiliary wiring 68b are electrically connected by the inter-cell wiring member 18.

The first light receiving surface finger electrode 60a and the first back surface finger electrode 64a are aligned opposite to each other in the direction of thickness of the solar cell 10. The same is also true of the third light receiving surface finger electrode 60c and the fourth back surface finger electrode 64d and of the fifth light receiving surface finger electrode 60e and the seventh back surface finger electrode 64g. For this reason, the pressure during pressure bonding is canceled in the light receiving surface 50 and the back surface 52. Meanwhile, the second light receiving surface finger electrode 60b and the fourth light receiving surface finger electrode 60d are not aligned with the opposite back surface finger electrode 64 in the direction of thickness of the solar cell 10. However, the second light receiving surface finger electrode 60b is aligned opposite to the first auxiliary wiring 68a, and the fourth light receiving surface finger electrode 60d is aligned opposite to the second auxiliary wiring 68b. Therefore, the pressure during pressure bonding is partly canceled in the light receiving surface 50 and the back surface 52. As a result, the shearing stress in the solar cell 10 is mitigated so that cracks are inhibited from occurring in the solar cell 10, and the yield is improved.

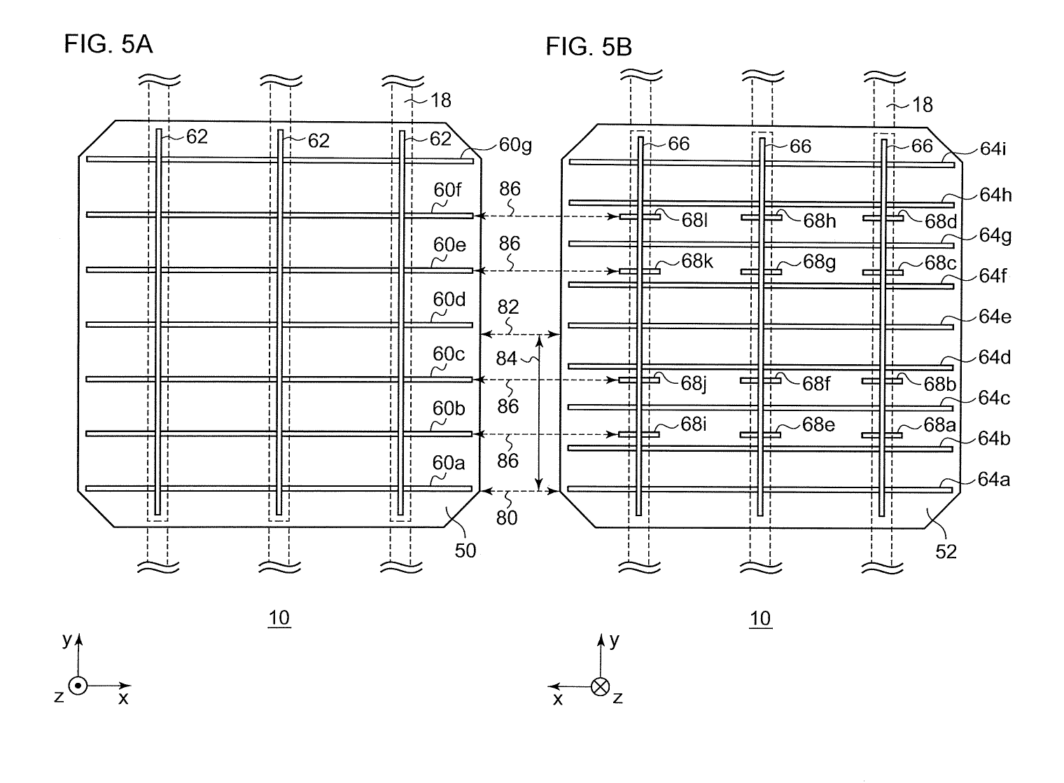

An example in which m, m1, and m2 have different values will be described below. FIGS. 5A-5B are plan views showing another structure of the solar cell 10. FIGS. 5A-5B are equivalent to FIGS. 3A-3B so that a difference will be described here. On the light receiving surface 50 of FIG. 5A, “seven” light receiving surface finger electrodes 60 including the first light receiving surface finger electrode 60a through the seventh light receiving surface finger electrode 60g are arranged in the y axis direction as the plurality of light receiving surface finger electrodes 60. Thus, n is “7”. On the back surface 52 of FIG. 5B, on the other hand, “nine” back surface finger electrodes 64 including the first back surface finger electrode 64a through the ninth back surface finger electrode 64i are arranged in the y axis direction as the plurality of back surface finger electrodes 64.

The first light receiving surface finger electrode 60a and the first back surface finger electrode 64a overlap, the fourth light receiving surface finger electrode 60d and the fifth back surface finger electrode 64e overlap, and the seventh light receiving surface finger electrode 60g and the ninth back surface finger electrode 64i overlap on the plane of projection. The first position 80, the second position 82, and the unit interval 84 are defined in a manner similar to that of FIGS. 3A-3B. The unit interval 84 includes three light receiving surface finger electrodes 60 and four back surface finger electrodes 64.

Thus, m1 is “4”, m2 is “3”, and m1>m2.

The third position 86 is defined in a manner similar that of FIGS. 3A-3B, and the auxiliary wiring 68 is provided on the back surface 52 at the third position 86. To describe it more specifically, the first auxiliary wiring 68a, the fifth auxiliary wiring 68e, and the ninth auxiliary wiring 68i are provided on the back surface 52 at the third position 86 defined for the second light receiving surface finger electrode 60b. Also, the second auxiliary wiring 68b, the sixth auxiliary wiring 68f, and the tenth auxiliary wiring 68j are provided on the back surface 52 at the third position 86 defined for the third light receiving surface finger electrode 60c. The same is true of the fifth light receiving surface finger electrode 60e and the sixth light receiving surface finger electrode 60f.

On the back surface 52, three auxiliary wirings 68 are provided between the second back surface finger electrode 64b and the third back surface finger electrode 64c, and three auxiliary wirings 68 are provided between the third back surface finger electrode 64c and the fourth back surface finger electrode 64d. This is generalized as follows:

The auxiliary wirings 68 are provided on the back surface 52 so as to be positioned between the m1/2−1-th back surface finger electrode 64 and the m1/2-th back surface finger electrode 64, counting from the back surface finger electrode 64 at the first position 80 on the plane of projection, n being an even number. The auxiliary wirings 68 are also provided on the back surface 52 so as to be positioned between the m1/2-th back surface finger electrode 64 and the m½+1-th back surface finger electrode 64, counting from the back surface finger electrode 64 at the first position 80 on the plane of projection, n being an even number. The back surface finger electrode 64 at the first position 80 on the plane of projection corresponds to the first back surface finger electrode 64a and the fifth back surface finger electrode 64e in FIG. 5B.

A description will now be given of a method of manufacturing the solar cell module 100. First, the stack is produced by successively layering the first protective member 40a, the first encapsulant 42a, the solar cell 10, etc. the second encapsulant 42b, and the second protective member 40b from the positive direction side toward the negative direction side along the z axis. This is followed by a laminate cure process performed for the stack. In this process, air is drawn from the stack, and the stack is heated and pressurized so as to be integrated. In vacuum lamination in the laminate cure process, the temperature is set to about 150°, as mentioned above.

According to the embodiment of the present disclosure, the number of the back surface finger electrodes 64 is inhibited from increasing by providing a total of n light receiving surface finger electrodes 60 on the light receiving surface 50 and providing (n−1)×m1/m2+1 back surface finger electrodes 64 on the back surface 52. Since the number of the back surface finger electrodes 64 is inhibited from increasing, the volume of silver paste etc. used is inhibited from increasing. Since the volume of silver paste, etc. used is inhibited from increasing, the cost is inhibited from increasing. Since the auxiliary wiring 68 is provided where only the light receiving surface finger electrode 60 is present, the pressure during pressure bonding is partly canceled in the light receiving surface 50 and the back surface 52. Since the stress is partly canceled, the shearing stress in the solar cell 10 is mitigated. Since the shearing pressure in the solar cell 10 is mitigated, cracks are inhibited from occurring in the solar cell 10. Further, since cracks are inhibited from occurring in the solar cell 10, the yield is improved.

The configuration of the embodiment provides a significant advantage especially when the number of the light receiving surface finger electrodes 60 and the number of the back surface finger electrodes 64 are related as follows.

$$500 µm > \vert ( \frac{ma}{{N}_{a} - 1} - \frac{mb}{{N}_{b} - 1} ) \vert A ( µm )$$

>width of light receiving surface finger electrode+back surface finger electrode (μm) (1)

Nₐ in the left term in the parenthesis denotes the number of the light receiving surface finger electrodes 60, i.e., the total number n as described above. Therefore, 1/(Nₐ−1) denotes the pitch of the light receiving surface finger electrodes 60. The symbol ma denotes the position of the ma-th light receiving surface finger electrode 60, counting from the light receiving surface finger electrode 60 at the end, and 1<ma<(Nₐ−1). Meanwhile, N_{b} in the right term in the parenthesis denotes the number of the back surface finger electrodes 64. Therefore, 1/(N_{b}−1) denotes the pitch of the light receiving surface bus bar electrodes 62. The symbol mb denotes the position of the mb-th light receiving surface bus bar electrode 62, counting from the light receiving surface bus bar electrode 62 at the end, and 1<mb<(N_{b}−1).

In other words, the expression above gives the distance between the ma-th light receiving surface finger electrode 60 and the mb-th light receiving surface bus bar electrode 62. If expression (1) is fulfilled within the plane of the solar cell 10 in at least one combination of (ma, mb), i.e., if the distance is larger than the total of the width of the light receiving surface finger electrode 60 and the width of the back surface finger electrode 64 or is equal to or smaller than 500 μm at any location within the plane of the solar cell 10, the relevant portion of the solar cell 10 easily undergoes a searing stress and is easily cracked. Therefore, the embodiment achieves a particularly significant advantage when the number of the light receiving surface finger electrodes 60 and the number of the back surface finger electrodes 64 are related as indicated above.

Since the length of the auxiliary wiring 68 is shorter than the interval between two adjacent inter-cell wiring members 18, the volume of silver paste, etc. used is reduced. Since the length of the auxiliary wiring 68 is larger than the width of the inter-cell wiring member 18, the quantity of cancellation of the pressure during pressure bonding is enlarged. The auxiliary wiring 68 is provided between the (m1−1)/2-th back surface finger electrode 64 and the (m1+1)/2-th back surface finger electrode 64, counting from the back surface finger electrode 64 at the first position 80, n being an odd number. Accordingly, the light receiving surface finger electrodes 60 are aligned with the respective opposite electrodes. The auxiliary wiring 68 is provided between the m½−1-th back surface finger electrode 64 and the m1/2-th back surface finger electrode 64, counting from the back surface finger electrode 64 at the first position 80, n being an even number. Accordingly, the light receiving surface finger electrodes 60 are aligned with the respective opposite electrodes. The auxiliary wiring 68 is also provided between the m1/2-th back surface finger electrode 64 and the m½+1-th back surface finger electrode 64, counting from the back surface finger electrode 64 at the first position 80, n being an even number. Accordingly, the light receiving surface finger electrodes 60 are aligned with the respective opposite electrodes.

A summary of the embodiment is given below. A solar cell module 100 according to an embodiment of the present disclosure includes: a plurality of solar cells 10 including a light receiving surface 50 and a back surface 52 that face in opposite directions; and a wiring member 18 that connects, of the plurality of solar cells 10, two solar cells 10 adjacent in a first direction. Each of the plurality of solar cells 10 includes: n light receiving surface finger electrodes 60 arranged on the light receiving surface 50 in the first direction; (n−1)×m1/m2+1 back surface finger electrodes 64 arranged on the back surface 52 in the first direction; and one or more auxiliary wirings 68 arranged on the back surface 52 in the first direction. On a plane of projection parallel to the light receiving surface 50 or the back surface 52, m2 light receiving surface finger electrodes 60 and m1 back surface finger electrodes 64 are included an interval between a first position 80 at which the light receiving surface finger electrode 60 and the back surface finger electrode 64 overlap and a second position 82 at which the light receiving surface finger electrode 60 and the back surface finger electrode 64 overlap next, the interval starting from the first position 80 in the first direction, on the plane of projection parallel to the light receiving surface 50 or the back surface 52, the auxiliary wiring 68 is provided on the back surface 52 at a third position 86 at which only the light receiving surface finger electrode 60 is present, a length of the auxiliary wiring 68 in a second direction intersecting the first direction is smaller than a length of the back surface finger electrode 64 in the second direction, and the inter-cell wiring member 18 is connected to the back surface finger electrode 64 and the auxiliary wiring 68 on the back surface 52 of the solar cell 10.

A plurality of inter-cell wiring members 18 are arranged on the back surface 52 in the second direction, and the length of the auxiliary wiring 68 in the second direction is smaller than an interval between the two inter-cell wiring members 18 adjacent in the second direction.

The length of the auxiliary wiring 68 in the second direction is larger than a width of the inter-cell wiring member 18 in the second direction.

The auxiliary wiring 68 is provided on the back surface 52 so as to be positioned between an (m1−1)/2-th back surface finger electrode 64 and an (m1+1)/2-th back surface finger electrode 64, counting from the back surface finger electrode 64 at the first position 80 on the plane of projection parallel to the light receiving surface 50 or the back surface 52, n being an odd number.

The auxiliary wiring 68 is provided on the back surface 52 so as to be positioned between an m½-1-th back surface finger electrode 64 and an m1/2-th back surface finger electrode 64 and positioned between an m1/2-th back surface finger electrode 64 and an m½+1-th back surface finger electrode 64, counting from the back surface finger electrode 64 at the first position 80 on the plane of projection parallel to the light receiving surface 50 and the back surface 52, n being an even number.

Another embodiment of the present disclosure related to the solar cell 10. A solar cell 10 includes a light receiving surface 50 and a back surface 52 that face in opposite directions; and n light receiving surface finger electrodes 60 arranged on the light receiving surface 50 in the first direction; (n−1)×m1/m2+1 back surface finger collecting electrodes 64 arranged on the back surface 52 in the first direction; and one or more auxiliary wirings 68 arranged on the back surface 52 in the first direction. On a plane of projection parallel to the light receiving surface 50 or the back surface 52, m2 light receiving surface finger electrodes 60 and m1 back surface finger electrodes 64 are included an interval between a first position 80 at which the light receiving surface finger electrode 60 and the back surface finger electrode 64 overlap and a second position 82 at which the light receiving surface finger electrode 60 and the back surface finger electrode 64 overlap next, the interval starting from the first position 80 in the first direction, on the plane of projection parallel to the light receiving surface 50 or the back surface 52, the auxiliary wiring 68 is provided on the back surface 52 at a third position 86 at which only the light receiving surface finger electrode 60 is present, and a length of the auxiliary wiring 68 in a second direction intersecting the first direction is smaller than a length of the back surface finger electrode 64 in the second direction.

Described above is an explanation based on an exemplary embodiment. The embodiment is intended to be illustrative only and it will be understood by those skilled in the art that various modifications to constituting elements and processes could be developed and that such modifications are also within the scope of the present invention.

In the embodiment, the case where n=7, m1=3, and m2=2 and the case where n=9, m1=4, and m2=3 are discussed. Alternatively, n, m1, and m2 may be such that n=55, m1=3, and m2=2. In that case, the number of the back surface finger electrodes 64 will be “82”. The values of n, m1, and m2 are not limited to these examples. According to this variation, the flexibility in the configuration is improved.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell module comprising:
a plurality of solar cells including a first surface and a second surface that face in opposite directions; and
a wiring member that connects, of the plurality of solar cells, two solar cells adjacent in a first direction, wherein
each of the plurality of solar cells includes:
n first collecting electrodes arranged on the first surface in the first direction;
(n−1)×m1/m2+1 second collecting electrodes arranged on the second surface in the first direction; and
one or more auxiliary wirings arranged on the second surface in the first direction, wherein
on a plane of projection parallel to the first surface or the second surface, m2 first collecting electrodes and m1 second collecting electrodes are included an interval between a first position at which the first collecting electrode and the second collecting electrode overlap and a second position at which the first collecting electrode and the second collecting electrode overlap next, the interval starting from the first position in the first direction,
on the plane of projection parallel to the first surface or the second surface, the auxiliary wiring is provided on the second surface at a third position at which only the first collecting electrode is present,
a length of the auxiliary wiring in a second direction intersecting the first direction is smaller than a length of the second collecting electrode in the second direction, and the wiring member is connected to the second collecting electrode and the auxiliary wiring on the second surface of the solar cell.

2. The solar cell module according to claim 1, wherein
a plurality of wiring members are arranged on the second surface in the second direction, and
the length of the auxiliary wiring in the second direction is smaller than an interval between the two wiring members adjacent in the second direction.

3. The solar cell module according to claim 1, wherein
the length of the auxiliary wiring in the second direction is larger than a width of the wiring member in the second direction.

4. The solar cell module according to claim 2, wherein
the length of the auxiliary wiring in the second direction is larger than a width of the wiring member in the second direction.

5. The solar cell module according to claim 1, wherein
the auxiliary wiring is provided on the second surface so as to be positioned between an (m1−1)/2-th second electrode and an (m1+1)/2-th second electrode, counting from the second electrode at the first position on the plane of projection parallel to the first surface or the second surface, n being an odd number.

6. The solar cell module according to claim 2, wherein
the auxiliary wiring is provided on the second surface so as to be positioned between an (m1−1)/2-th second electrode and an (m1+1)/2-th second electrode, counting from the second electrode at the first position on the plane of projection parallel to the first surface or the second surface, n being an odd number.

7. The solar cell module according to claim 3, wherein
the auxiliary wiring is provided on the second surface so as to be positioned between an (m1−1)/2-th second electrode and an (m1+1)/2-th second electrode, counting from the second electrode at the first position on the plane of projection parallel to the first surface or the second surface, n being an odd number.

8. The solar cell module according to claim 4, wherein
the auxiliary wiring is provided on the second surface so as to be positioned between an (m1−1)/2-th second electrode and an (m1+1)/2-th second electrode, counting from the second electrode at the first position on the plane of projection parallel to the first surface or the second surface, n being an odd number.

9. The solar cell module according to claim 1, wherein
the auxiliary wiring is provided on the second surface so as to be positioned between an m½-1-th second electrode and an m1/2-th second electrode and positioned between an m1/2-th second electrode and an m½+1-th second electrode, counting from the second electrode at the first position on the plane of projection parallel to the first surface and the second surface, n being an even number.

10. The solar cell module according to claim 2, wherein
the auxiliary wiring is provided on the second surface so as to be positioned between an m½-1-th second electrode and an m1/2-th second electrode and positioned between an m1/2-th second electrode and an m½+1-th second electrode, counting from the second electrode at the first position on the plane of projection parallel to the first surface and the second surface, n being an even number.

11. The solar cell module according to claim 3, wherein
the auxiliary wiring is provided on the second surface so as to be positioned between an m1/2-1-th second electrode and an m1/2-th second electrode and positioned between an m1/2-th second electrode and an m1/2+1-th second electrode, counting from the second electrode at the first position on the plane of projection parallel to the first surface and the second surface, n being an even number.

12. The solar cell module according to claim 4, wherein
the auxiliary wiring is provided on the second surface so as to be positioned between an m½-1-th second electrode and an m1/2-th second electrode and positioned between an m1/2-th second electrode and an m½+1-th second electrode, counting from the second electrode at the first position on the plane of projection parallel to the first surface and the second surface, n being an even number.

13. A solar cell including a first surface and a second surface that face in opposite directions; and
n first collecting electrodes arranged on the first surface in the first direction;
(n−1)×m1/m2+1 second collecting electrodes arranged on the second surface in the first direction; and
one or more auxiliary wirings arranged on the second surface in the first direction, wherein
on a plane of projection parallel to the first surface or the second surface, m2 first collecting electrodes and m1 second collecting electrodes are included an interval between a first position at which the first collecting electrode and the second collecting electrode overlap and a second position at which the first collecting electrode and the second collecting electrode overlap next, the interval starting from the first position in the first direction,
on the plane of projection parallel to the first surface or the second surface, the auxiliary wiring is provided on the second surface at a third position at which only the first collecting electrode is present, and
a length of the auxiliary wiring in a second direction intersecting the first direction is smaller than a length of the second collecting electrode in the second direction.
